(19) United States
(12) Patent Application Publication
(10) Pub. No.: US 2025/0228042 A1
(43) Pub. Date: Jul. 10, 2025

(54) LIGHT EMITTING DEVICES HAVING ALUMINUM INDIUM GALLIUM PHOSPHIDE DIE WITH EMBEDDED CONTACTS

(71) Applicant: Lumileds LLC, San Jose, CA (US)

(72) Inventors: Toni Lopez, Vaals (NL); Theodore Chung, Santa Clara, CA (US); Erik William Young, San Jose, CA (US)

(73) Assignee: Lumileds LLC, San Jose, CA (US)

(21) Appl. No.: 18/406,634

(22) Filed: Jan. 8, 2024

(51) Int. Cl. H01L 33/38; H01L 33/00; H01L 33/06; H01L 33/30; H01L 33/40

(52) U.S. Cl. CPC H10H 20/831; H10H 20/0133; H10H 20/812; H10H 20/824; H10H 20/032; H10H 20/832

(57) ABSTRACT

A vertical thin-film (VTF) light emitting diode (LED) having embedded contacts is described. The vertical thin-film (VTF) light emitting diode (LED) having embedded contacts has structure where the metal layer constitutes both bondpad(s) and associated electric contact to the semiconductor. The metal layer is embedded and, hence, no longer blocking light from the light emitting surface. The vertical thin-film (VTF) light emitting diode (LED) having embedded contacts comprises a plurality of group III-V semiconductor material layers, including binary, ternary, and quaternary alloys of gallium (Ga), aluminum (Al), indium (In), and phosphorus (P) and a multiple quantum well layer on a substrate. At least one ne of the plurality of group III-V semiconductor material layers comprise an aluminum indium phosphide (AlInP) layer or a low confinement layer (LCL) comprising aluminum indium gallium phosphide (AlInGaP).

### TECHNICAL FIELD

Embodiments of the disclosure generally relate to light emitting diode (LED) devices and methods of manufacturing the same. More particularly, embodiments are directed to a die/epi design for aluminum indium gallium phosphide (AlInGaP) with embedded metal-semiconductor contacts.

### BACKGROUND

Light emitting diodes (LED) have emerged as an appealing light source for many applications. From road signage and traffic signals, LEDs are becoming dominant in general lighting, automotive lighting, mobile electronics, camera flash, display backlighting, horticulture, sanitization, and other applications.

A light emitting diode (LED) is a semiconductor light source that emits visible light when current flows through it. LEDs combine a P-type semiconductor with an N-type semiconductor. LEDs commonly use a III-V group compound semiconductor. A III-V group compound semiconductor provides stable operation at a higher temperature than devices that use other semiconductors. Frequently, the LEDs are formed on a sapphire substrate.

In vertical thin-film (VTF) LEDs, the sapphire substrate is removed, and the LED structure is transferred to an electrically conductive substrate and current injection occurs vertically. Typically, with VTF LEDs, electrical contacts are deposited on both sides of the functional epilayers. Optical performance with VTF LEDs, however, can be poor.

Accordingly, there is a need for vertical thin-film (VTF) architectures with improved optical performance.

### SUMMARY

Embodiments of the disclosure are directed to vertical thin-film (VTF) light emitting diode (LED) with embedded contacts and methods for manufacturing vertical thin-film (VTF) light emitting diode (LED). In one or more embodiments, a vertical thin-film (VTF) light emitting diode (LED) comprises: an epitaxial stack comprising a plurality of group III-V semiconductor material layers, including binary, ternary, and quaternary alloys of gallium (Ga), aluminum (Al), indium (In), and phosphorus (P) and a multiple quantum well layer on a substrate, wherein at least one of the plurality of group III-V semiconductor material layers is a low confinement layer (LCL) comprising aluminum indium gallium phosphide (AlInGaP); a first dielectric layer on the epitaxial stack; an n-contact and a p-contact within the first dielectric layer; and a metal layer on the first dielectric layer in electrical contact with the plurality of group III-V semiconductor material layers.

Further embodiments of the disclosure are directed to methods of manufacturing a vertical thin-film (VTF) LED device. In one or more embodiments, a method of manufacturing a vertical thin-film (VTF) LED device comprises: sequentially forming a plurality of group III-V semiconductor material layers, including binary, ternary, and quaternary alloys of gallium (Ga), aluminum (Al), indium (In), and phosphorus (P) and a multiple quantum well layer to form an epitaxial stack on a substrate, wherein at least one of the plurality of group III-V semiconductor material layers is a low confinement layer (LCL) comprising aluminum indium gallium phosphide (AlInGaP); depositing a first dielectric layer on the epitaxial stack; removing a portion of the first dielectric layer to form openings in the dielectric layer, the openings exposing the plurality of group III-V semiconductor material layers; forming a P-contact in the openings in the dielectric layer; forming a metal layer on the first dielectric layer in electrical contact with the plurality of group III-V semiconductor material layers; forming a bond pad; depositing a second dielectric layer on the metal layer; and forming an N-contact on the epitaxial stack.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 is a cross-section schematic view of a VTF LED device structure according to the prior art;

FIG. 2 illustrates a process flow diagram of a method of manufacturing an LED according to one or more embodiments;

FIG. 3 illustrates a cross-section schematic of an epitaxy configuration according to one or more embodiments;

FIG. 4 illustrates a cross-section schematic of the epitaxy configuration after processing into a VTF LED device according to one of more embodiments;

FIG. 5 illustrates an enlarged cross-section schematic of the VTF LED device of FIG. 5;

FIG. 6A illustrates a cross-section schematic of the epitaxy configuration after processing into a vertical thin-film (VTF) LED device with embedded contacts according to one or more embodiments; and

FIG. 6B illustrates a cross-section schematic of the epitaxy configuration after processing into a vertical thin-film (VTF) LED device with embedded contacts according to one or more embodiments.

To facilitate understanding, identical reference numerals have been used, where possible, to designate identical elements that are common to the figures. The figures are not drawn to scale. For example, the heights and widths of the mesas are not drawn to scale.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate or on a substrate with one or more layers, films, features, or materials deposited or formed thereon.

In one or more embodiments, the “substrate” means any substrate or material surface formed on a substrate upon which film processing is performed during a fabrication process. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AlN, InN, and other alloys), metal alloys, and other conductive materials, depending on the application. Substrates include, without limitation, light emitting diode (LED) devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed is also performed on an underlayer formed on the substrate, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “wafer” and “substrate” will be used interchangeably in the instant disclosure. Thus, as used herein, a wafer serves as the substrate for the formation of the LED devices described herein.

Reference to LED refers to a light emitting diode that emits light when current flows through it. In one or more embodiments, the LEDs herein have one or more characteristic dimensions (e.g., height, width, depth, thickness, etc. dimensions) in a range of greater than or equal to 75 micrometers to less than or equal to 300 micrometers. In one or embodiments, one or more dimensions of height, width, depth, thickness have values in a range of 100 to 300 micrometers. Reference herein to micrometers allows for variation of +1-5%. In one or more embodiments, one or more dimensions of height, width, depth, thickness have values of 200 micrometers+1-5%. In some instances, the LEDs are referred to as micro-LEDs (uLEDs or μLEDs), referring to a light emitting diode having one or more characteristic dimensions (e.g., height, width, depth, thickness, etc. dimensions) on the order of micrometers or tens of micrometers. In one or embodiments, one or more dimensions of height, width, depth, thickness have values in a range of 1 to less than 75 micrometers, for example from 1 to 50 micrometers, or from 1 to 25 micrometers. Overall, in one or more embodiments, the LEDs herein may have a characteristic dimension ranging from 1 micrometer to 300 micrometers, and all values and sub-ranges therebetween.

Examples of different light illumination systems and/or light emitting diode (LED) implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

Semiconductor light emitting devices or optical power emitting devices, such as devices that emit ultraviolet (UV) or infrared (IR) optical power, are among the most efficient light sources currently available. These devices may include light emitting diodes, resonant cavity light emitting diodes, vertical cavity laser diodes, edge emitting lasers, or the like (hereinafter referred to as “LEDs”). Due to their compact size and lower power requirements, for example, LEDs may be attractive candidates for many different applications. For example, they may be used as light sources (e.g., flashlights and camera flashes) for hand-held battery-powered devices, such as cameras and cell phones. They may also be used, for example, for automotive lighting, heads up display (HUD) lighting, horticultural lighting, street lighting, torch for video, general illumination (e.g., home, shop, office and studio lighting, theater/stage lighting and architectural lighting), augmented reality (AR) lighting, virtual reality (VR) lighting, as back lights for displays, and IR spectroscopy. A single LED may provide light that is less bright than an incandescent light source, and, therefore, multi-junction devices or arrays of LEDs (such as monolithic LED arrays, micro-LED arrays, etc.) may be used for applications where more brightness is desired or required.

In a vertical thin-film (VTF) LED, the LED structure is on an electrically conductive substrate and current injection occurs vertically. The present disclosure generally relates to the manufacture of vertical thin-film (VTF) LEDs with embedded contacts. As used herein, the term “embedded contacts” refers to a structure where the metal layer constitutes both bondpad(s) and associated electric contact to the semiconductor. In one or more embodiments, the metal layer is now embedded and, hence, no longer blocking light from the light emitting surface. In one or more embodiments, the metal layer may be electrically contacting either the n-type semiconductor or the p-type semiconductor. For ease of illustration, the drawings herein show the metal layer electrically contacting the p-type semiconductor, but one of skill in the art recognizes that the Figures are non-limiting, and the metal layer may contact the n-type semiconductor.

In one or more embodiments, the epitaxial material used in the VTF LED device with embedded contacts advantageously comprises aluminum indium gallium phosphide (AlInGaP) having a layer that is 100% aluminum indium phosphide (AlInP) or a low confinement layer (LCL) layer with a composition x that is less than 100% aluminum indium gallium phosphide ((AlₓGa₁₋ₓ)_{0.5}In_{0.5}P). Additionally, in one or more embodiments, the proposed VTF LED device advantageously includes an embedded contact. The epitaxy configuration of one or more embodiments provides improved optical performance and efficacy Im/W. As used herein, the term “efficacy Im/W” refers to the ratio of the output total lumens to the input electrical power (W).

The embodiments of the disclosure are described by way of the Figures, which illustrate devices and processes for forming devices in accordance with one or more embodiments of the disclosure. The processes shown are merely illustrative possible uses for the disclosed processes, and the skilled artisan will recognize that the disclosed processes are not limited to the illustrated applications.

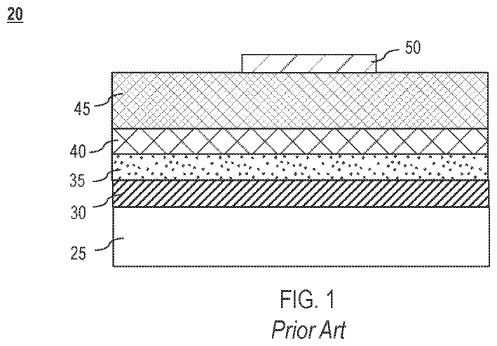

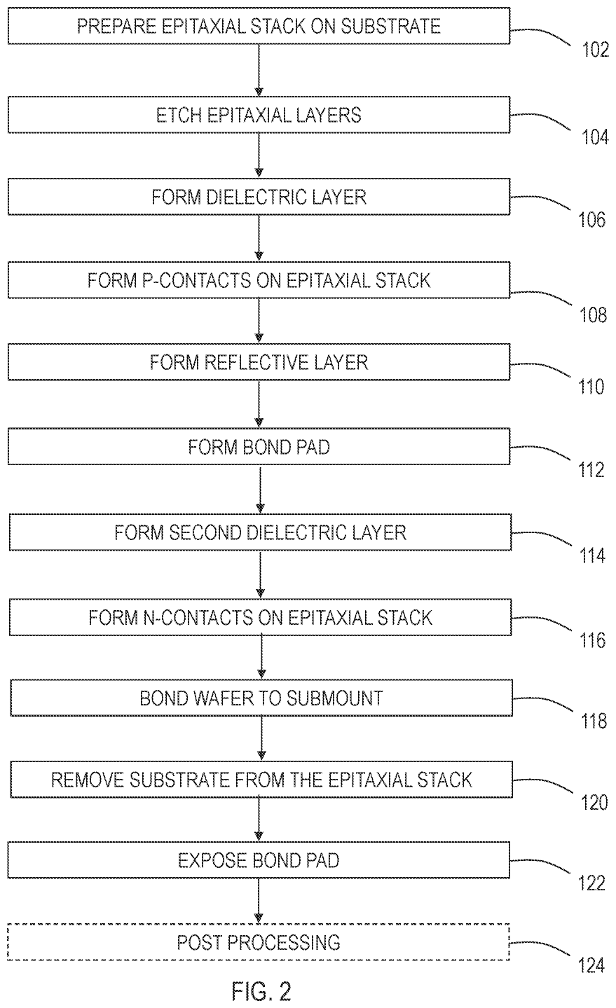

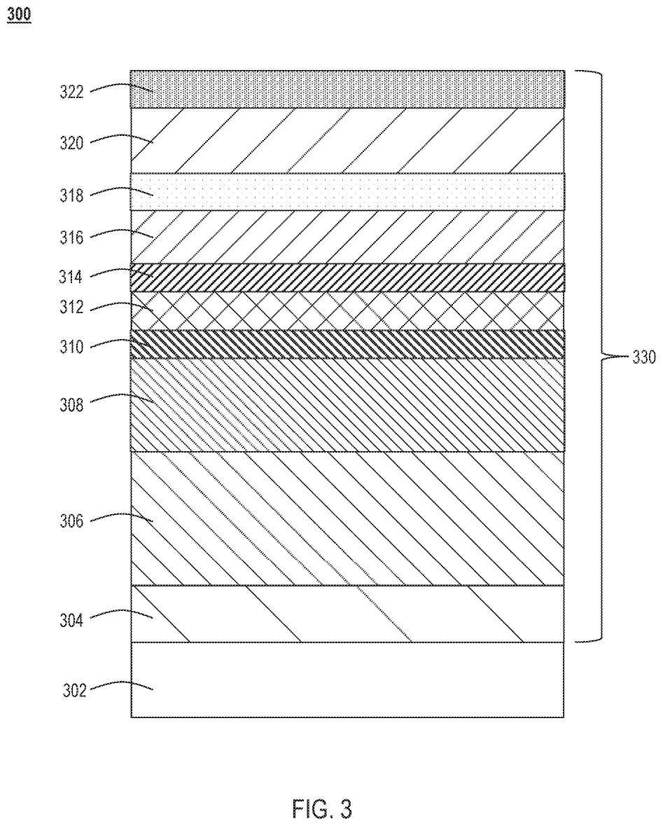

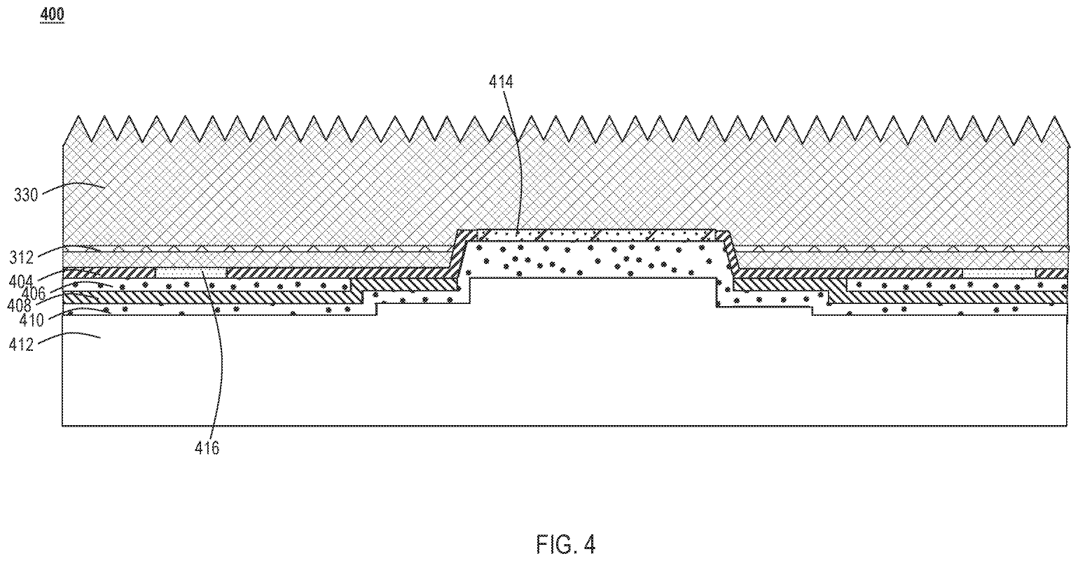

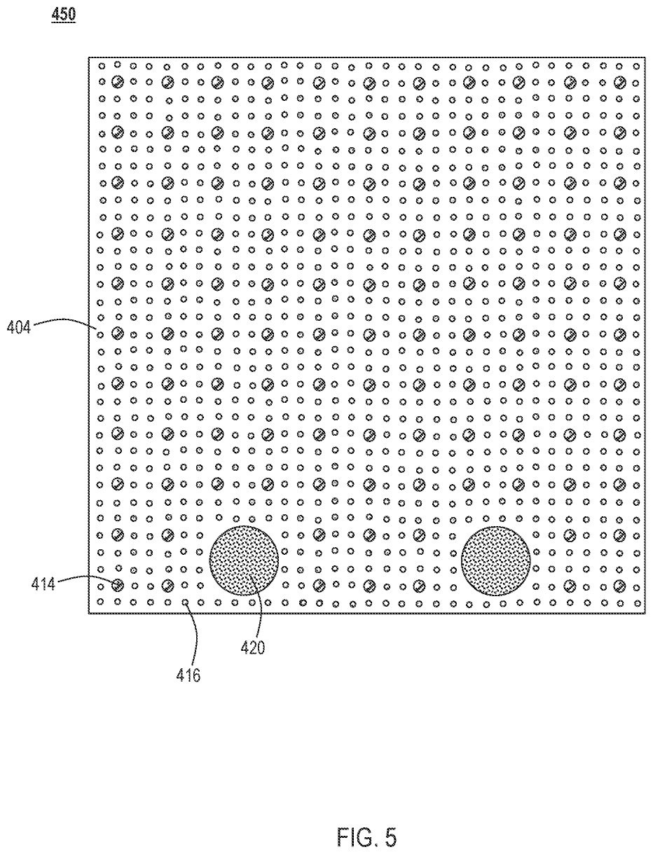

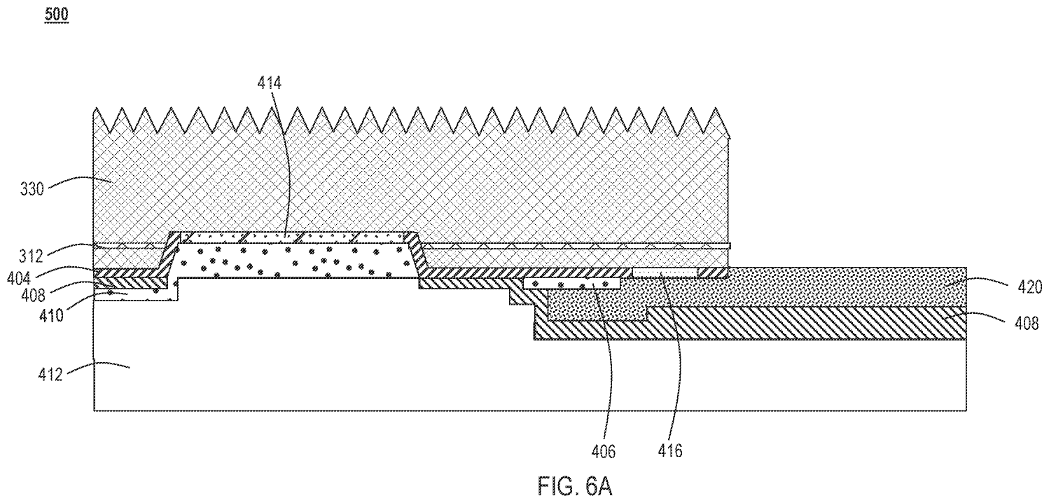

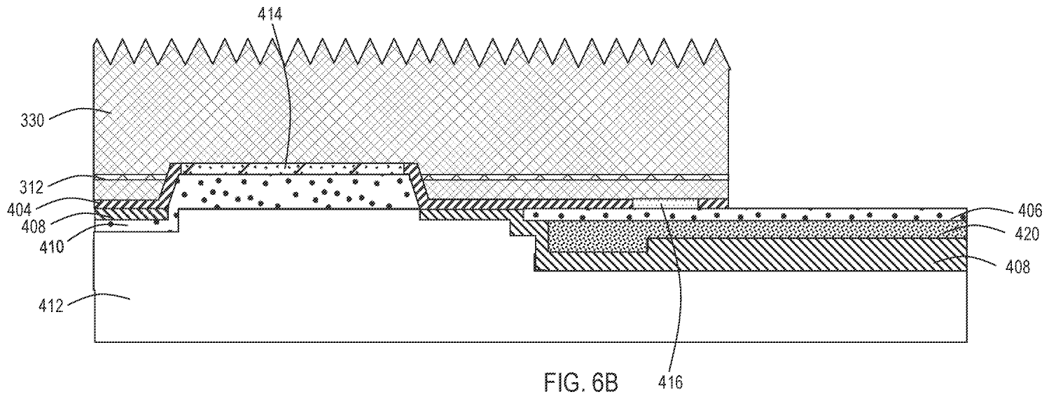

One or more embodiments of the disclosure are described with reference to the Figures. FIG. 1 illustrates a cross-section schematic view of a VTF LED device structure according to the prior art. FIG. 2 illustrates a process flow diagram for a method 100 of manufacturing a VTF LED device with embedded contacts according to one or more embodiments. FIG. 3 illustrates a cross-section schematic of an epitaxy configuration according to one or more embodiments. FIG. 4 illustrates a cross-section schematic of a VTF LED device structure having embedded contacts according to one of more embodiments. FIG. 5 illustrates an enlarged cross-section schematic of the VTF LED device of FIG. 5. FIGS. 6A and 6B illustrate a cross-section schematic of the epitaxy configuration after processing into vertical thin-film (VTF) LED device with embedded contacts according to one or more embodiments.

FIG. 1 is a cross-section schematic view of a LED device 20 according to the prior art. The LED device 20 is representative of a traditional vertical thin film (VTF) die. The LED device 20 comprises an LED substrate 25, semiconductor layers including a p-type layer 35, an active layer 40, and an n-type layer 45. A reflector material 30 is on the LED substrate. The LED device 20 may be packaged and/or assembled singly or with other LED devices. Other features may be added to the LED device 20 for desired applications. N-type contact busbars and bondpads 50 may be formed on a top surface of the semiconductor layers. In one or more embodiments, the bondpad metal layer 50 is on the light emitting surface and can also be n-type or p-type semiconductor. The VTF LED of FIG. 1 is problematic in that the busbars and bond pads block light at the escape interface.

FIG. 2 provides a process flow diagram 100 for manufacture of a vertical thin-film (VTF) light emitting diode (LED) device with embedded contacts according to one or more embodiments. At operation 102, an epitaxial stack, including N-type layers, active region, and P-type layers are prepared according to methods known in the art. In one or more embodiments, the semiconductor layers of the epitaxial stack are formed by epitaxial (EPI) growth. In one or more embodiments, the process starts with an LED EPI wafer, which wafer can be grown by any of the conventional growth techniques used in LED manufacturing or research and could be of different material systems including but not limited to group III-V semiconductor material layers, including binary, ternary, and quaternary alloys of gallium (Ga), aluminum (Al), indium (In), and phosphorus (P).

At operation 104, the epitaxial layers are etched. At operation 106, one or more dielectric layers are deposited as needed for insulating and other purposes, e.g., layering, insulating, and contacting.

At operation 108, a plurality of anodes is formed on the epitaxial stack. Anodes include segmented P-contact layers, e.g., anode current spreading layers, and one or more P-contact materials and anode metallization bumps. A cathode is constructed by various deposition and patterning techniques as-needed for deposition of N-contact materials and insulating purposes.

At operation 110, a reflective metal layer is formed.

At operation 112, the bond pad metallization is formed.

At operation 114, one or more second dielectric layers are deposited as needed for insulating and other purposes.

At operation 116, a plurality of cathodes of N-contacts is formed on the epitaxial stack. A cathode is constructed by various deposition and patterning techniques as-needed for deposition of N-contact materials and insulating purposes. Deposition of the electrode material for the common cathode and the anodes may be done simultaneously, subject to later patterning and dielectric deposition.

At operation 118, the wafer is bonded to a submount.

At operation 120, the epitaxial stack is removed from the substrate. Removal from the substrate can be done by any suitable process known to the skilled artisan, including, but not limited to, laser lift-off.

At operation 122, the bond pad is exposed.

At operation 124, optional further post-processing is performed. In one or more embodiments, further processing may include formation of a passivation layer around a portion or the entirety of the array. In one or more embodiments, the processed structure retains the substrate, and is further processed. In one or more embodiments, the processed structure is flipped and affixed to a support, for example, a tape support, and the substrate is removed. Removal of the substrate is in accordance with methods known in the art including substrate laser liftoff.

Referring to FIG. 3, the epitaxial growth steps for the vertical thin-film (VTF) LED device with embedded contacts are described. FIG. 3 illustrates a cross-sectional view of an epitaxial structure 300 according to one or more embodiments. An aspect of the disclosure pertains to a method of manufacturing a VTF LED device with embedded contacts.

Referring to FIG. 3, an epitaxial structure 300 is manufactured by forming a plurality of a plurality of group III-V semiconductor material layers, including binary, ternary, and quaternary alloys of gallium (Ga), aluminum (Al), indium (In), and phosphorus (P) and a multiple quantum well layer on a substrate 302. Any order of stacking the different layers and active regions is within the scope of the disclosure.

In one or more embodiments, a plurality of epitaxial layers 330 are formed on a substrate 302. The substrate 302 may be any substrate known to one of skill in the art which is configured for use in the formation of VTF LED devices with embedded contacts. In one or more embodiments, the substrate 302 comprises one or more of gallium arsenide (GaAs), and the like. In one or more embodiments, the substrate 302 is not patterned prior to formation of the VTF LED devices with embedded contacts. Thus, in some embodiments, the substrate is 302 not patterned and can be considered to be flat or substantially flat. In other embodiments, the substrate 302 is a patterned substrate. The substrate 302 may have any suitable thickness known to the skilled artisan. In one or more embodiments, the substrate 302 has a thickness in a range of from 0.5 μm to 1 μm.

According to certain specific embodiments, the epitaxial structure 300 includes a plurality of epitaxial layers or an epitaxial stack 330 having a first layer 304 on the substrate 302, a second layer 306 on the first layer 304, a third layer 308 on the second layer, a fourth layer 310 on the third layer 308, multiple quantum wells 312 on the fourth layer 310, a fifth layer 314 on the multiple quantum wells 312, a sixth layer 316 on the fifth layer 314, a transition layer 318 on the sixth layer 316, a seventh layer 320 on the transition layer 318, and an eighth layer 322 on the seventh layer 320.

The epitaxial stack 330 may have any suitable thickness. In one or more embodiments, the epitaxial stack 330 has a thickness in a range of from 1 μm to 10 μm, including a range of from 2 μm to 7 μm, and a range of from 3 μm to 6 μm. In one or more specific embodiments, the epitaxial stack 330 has a thickness of about 5 μm, including about 4.5 μm.

Methods of forming or growing semiconductor layers including N-type layers, active regions, and P-type layers are formed according to methods known in the art. In one or more embodiments, the semiconductor layers are formed by epitaxial (EPI) growth. The semiconductor layers according to one or more embodiments comprise epitaxial layers or group III-V semiconductor material layers, including binary, ternary, and quaternary alloys of gallium (Ga), aluminum (Al), indium (In), and phosphorus (P). Thus, in some embodiments, the semiconductor layers comprise one or more of gallium (Ga), aluminum (Al), indium (In), nitrogen (N), phosphorus (P), gallium phosphide (GaP), aluminum phosphide (AIP), indium phosphide (InP), aluminum gallium phosphide (AlGaP), indium gallium phosphide (InGaP), indium aluminum phosphide (InAlP), aluminum indium gallium phosphide (AlInGaP), and the like. The group III-V semiconductor material layers may be doped with one or more of silicon (Si), oxygen (O), boron (B), phosphorus (P), germanium (Ge), zinc (Zn), magnesium (Mg), or carbon (C), depending upon whether p-type or n-type group III-V semiconductor material layers is needed. In one or more embodiments, the semiconductor layers have a combined thickness in a range of from about 2 μm to about 10 μm, and all values and subranges therebetween.

Devices and methods herein advantageously offer VTF LED devices with embedded contacts with individually electrically addressable light-emitting pixels without segmentation of epitaxial layers. Such arrays are useful where strict optical isolation is not necessary. VTF LED devices with embedded contacts according to one or more embodiments comprise non-segmented pixels in a light-emitting pixel area integral to a monolithic body, a plurality of anodes in contact with a P-type layer, and a cathode. These VTF LED devices with embedded contacts offer the following advantages: maximized optical efficiency, improved optical appearance without pixilation effects; and improved mechanical stability as compared to full or partial metal-filled trenches between pixels. In one or more embodiments, the VTF LED devices with embedded contacts herein are further advantageous over state-of-the-art VTF LED devices with respect to efficiency, optical performance, and electrical injection.

Referring to FIG. 3, in one or more embodiments, the first layer 304, the second layer 306, and the fourth layer 310 may comprise any Group III-V semiconductor material, including binary, ternary, and quaternary alloys of gallium (Ga), aluminum (Al), indium (In), and phosphorus (P). Thus, in some embodiments, the first layer 304, the second layer 306, and the fourth layer 310 comprise aluminum indium gallium phosphide (AlInGaP). Aluminum indium gallium phosphide (AlInGaP) is a semiconductor material that provides a platform for the manufacture of light-emitting diodes of high-brightness red, orange, green, and yellow color. AlInGaP may be grown by any suitable means known to the skilled artisan. In some embodiments, AlInGaP may be grown by heteroepitaxy. In one or more embodiments, the first layer 304, the second layer 306, and the fourth layer 310 are independently doped with n-type dopants, such as silicon (Si) or tellurium (Te). In one or more embodiments, the dopant concentration is in a range of from 1 e17 to 2e19 cm³.

In one or more embodiments, the third layer 308 and the sixth layer 316 may comprise any Group III-V semiconductor material, including binary, ternary, and quaternary alloys of gallium (Ga), aluminum (Al), indium (In), and phosphorus (P). Thus, in some embodiments, the third layer 308 and the sixth layer 316 comprise aluminum indium phosphide (AlInP). In one or more embodiments, the third layer 308 and the sixth layer 316 may be independently doped with any suitable n-type or p-type dopant known to the skilled artisan. In one or more embodiments, the third layer 308 and the sixth layer 316 may independently be doped with one or more of silicon (Si), tellurium (Te), carbon (C), or magnesium (Mg). In one or more embodiments, the dopant concentration is in a range of from 1e17 cm³ to 2e20 cm³.

In one or more embodiments, the first layer 304 comprises aluminum gallium indium phosphate (AlGaInP). The first layer may be doped with one or more n-type dopant. In some embodiments, the dopant comprises silicon (Si). In one or more embodiments, the dopant concentration is in a range of from 1e17 cm³ to 2e20 cm³. In one or more embodiments, the first layer 304 may have any suitable concentration of aluminum gallium indium phosphate (AlGaInP) depending upon the desired characteristics of the layer. In one or more embodiments, the first layer 304 contains about 50% aluminum gallium indium phosphate (AlGaInP). Without intending to be bound by theory, it is thought that keeping the first layer 304 having about 50% aluminum gallium indium phosphate ((AlₓGa₁₋ₓ)_{0.5}In_{0.5}P) will provide a lower refractive index layer and improve extraction. The first layer 304 may have any suitable thickness. In one or more embodiments, the first layer 304 has a thickness in a range of from greater than 0 μm to 1 μm, including about 0.1 μm, about 0.2 μm, about 0.3 μm, about 0.4 μm, about 0.5 μm, about 0.6 μm, about 0.7 μm, about 0.8 μm, about 0.9 μm, and about 1 μm.

In one or more embodiments, the second layer 306 is a low confinement layer (LCL). In one or more embodiments, the second layer 306 comprises aluminum indium gallium phosphide (AlInGaP). In one or more embodiments, the second layer 306 may have any suitable concentration of aluminum indium gallium phosphide (AlInGaP) depending upon the desired characteristics of the layer. In one or more embodiments, the second layer 306 contains in a range of from about 30% to about 40% aluminum indium gallium phosphide (AlInGaP). The second layer 306 may have any suitable thickness. In one or more embodiments, the second layer 306 has a thickness in a range of from 2 μm to 5 μm, including about 2.0 μm, about 2.5 μm, about 3.0 μm, about 3.5 μm, about 4.0 μm, about 4.5 μm, and about 5.0 μm.

In one or more embodiments, the third layer 308 is an n-contact layer. In one or more embodiments, the third layer 308 comprises aluminum indium phosphide (AlInP). The third layer 308 may be doped with one or more n-type dopant. In some embodiments, the dopant comprises silicon (Si). In one or more embodiments, the dopant concentration is in a range of from 1e17 cm³ to 2e19 cm³. In one or more embodiments, the third layer 308 may have any suitable concentration of aluminum indium phosphide (AlInP) depending upon the desired characteristics of the layer. The third layer 308 may have any suitable thickness. In one or more embodiments, the third layer 308 has a thickness in a range of from 0.5 μm to 2.0 μm, including in a range of from 1.0 μm to 1.5 μm. In some embodiments, the thickness of the third layer 308 is dependent upon the etch tolerance.

In one or more embodiments, the fourth layer 310 comprises aluminum indium gallium phosphide (AlInGaP). In one or more embodiments, the fourth layer 310 may have any suitable concentration of aluminum indium gallium phosphide (AlInGaP) depending upon the desired characteristics of the layer. The fourth layer 310 may have any suitable thickness. In one or more embodiments, the fourth layer 310 has a thickness of greater than 0 μm to less than 0.5 μm, including a thickness in a range of from greater than 0 μm to less than 0.4 μm, a range of from greater than 0 μm to less than 0.3 μm, a range of from greater than 0 μm to less than 0.2 μm, and a range of from greater than 0 μm to less than 0.1 μm.

In one or more embodiments, the term “quantum well” refers to a potential well with discrete energy values including a heterostructure made up of thin layers of semiconductor materials with different bandgaps. Periodic structures of repeated quantum wells that have barriers that are too thick for adjacent wave functions to couple are referred to as multiple quantum well (MQW) structures. In one or more embodiments, there is a multiple quantum well layer 312 on the fourth layer 310.

In one or more embodiments, a fifth layer 314 is on the multiple quantum well layer 312. In one or more embodiments, the fifth layer comprises aluminum (Al). The fifth layer 314 may comprise any suitable concentration of aluminum. In some embodiments, the fifth layer 314 comprises in a range of from 65% to 70% aluminum (Al). Without intending to be bound by theory, it is thought that a higher aluminum concentration provides for better n-contact formation. The fifth layer 314 may have any suitable thickness. In one or more embodiments, the fifth layer 314 has a thickness in a range of from greater than 0 μm to 2 μm, including a range of from greater than 0 μm to 0.15 μm.

In one or more embodiments, a sixth layer 316 is formed on the fifth layer 314. In one or more embodiments, the sixth layer 316 is a p-type layer. In some embodiments, the sixth layer 316 comprises aluminum indium phosphide (AlInP). The sixth layer 316 may be doped with one or more p-type dopant. In some embodiments, the dopant comprises magnesium (Mg). In one or more embodiments, the dopant concentration is in a range of from 1e17 cm³ to 2e19 cm³. In one or more embodiments, the sixth layer 316 may have any suitable concentration of aluminum indium phosphide (AlInP) depending upon the desired characteristics of the layer. The sixth layer 316 may have any suitable thickness. In one or more embodiments, the sixth layer 316 has a thickness in a range of from greater than 0 μm to 2.0 μm, including in a range of from 0.1 μm to 1.0 μm, and a range of from 0.2 μm to 0.5 μm.

In one or more embodiments, a transition layer 318 is formed on the sixth layer 316. In one or more embodiments, the transition layer 316 comprises a material having a composition x in the range of 0% to 50% in (AlₓGa₁₋ₓ)_{0.5}In_{0.5}P, which can also be graded (x goes from 30% to 0%). The transition layer 318 may have any suitable thickness. In one or more embodiments, the transition layer 318 has a thickness of greater than 0 μm to less than 0.5 μm, including a thickness in a range of from greater than 0 μm to less than 0.4 μm, a range of from greater than 0 μm to less than 0.3 μm, a range of from greater than 0 μm to less than 0.2 μm, and a range of from greater than 0 μm to less than 0.1 μm.

In one or more embodiments, a seventh layer 320 is formed on the transition layer. In one or more embodiments, the seventh layer 320 comprises a p-type layer. In one or more embodiments, the seventh layer 320 comprises gallium phosphide (GaP). The seventh layer 320 may be doped with one or more p-type dopant. In some embodiments, the dopant comprises magnesium (Mg). In one or more embodiments, the dopant concentration is in a range of from 1e17 cm³ to 2e19 cm³. In one or more embodiments, the seventh layer 320 has a thickness in a range of from greater than 0 μm to 2.0 μm, including in a range of from 0.1 μm to 1.0 μm, and a range of from 0.2 μm to 0.7 μm.

In one or more embodiments, an eighth layer 322 is formed on the seventh layer 320. In one or more embodiments, the eighth layer 322 comprises a p-type layer. In one or more embodiments, the eighth layer 322 comprises gallium phosphide (GaP). The eighth layer 322 may be doped with one or more p-type dopant. In some embodiments, the dopant comprises carbon (C). In one or more embodiments, the dopant concentration is in a range of from 1e17 cm³ to 2e20 cm³. In one or more embodiments, the eighth layer 322 has a thickness in a range of from greater than 0 μm to less than 0.4 μm, a range of from greater than 0 μm to less than 0.3 μm, a range of from greater than 0 μm to less than 0.2 μm, and a range of from greater than 0 μm to less than 0.1 μm.

In one or more embodiments, the layers of Group III-V semiconductor material, including binary, ternary, and quaternary alloys of gallium (Ga), aluminum (Al), indium (In), and phosphorus (P), may be deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD).

“Sputter deposition” as used herein refers to a physical vapor deposition (PVD) method of thin film deposition by sputtering. In sputter deposition, a material, e.g., a Ill-nitride, is ejected from a target that is a source onto a substrate. The technique is based on ion bombardment of a source material, the target. Ion bombardment results in a vapor due to a purely physical process, i.e., the sputtering of the target material.

As used according to some embodiments herein, “atomic layer deposition” (ALD) or “cyclical deposition” refers to a vapor phase technique used to deposit thin films on a substrate surface. The process of ALD involves the surface of a substrate, or a portion of substrate, being exposed to alternating precursors, i.e., two or more reactive compounds, to deposit a layer of material on the substrate surface. When the substrate is exposed to the alternating precursors, the precursors are introduced sequentially or simultaneously. The precursors are introduced into a reaction zone of a processing chamber, and the substrate, or portion of the substrate, is exposed separately to the precursors.

As used herein according to some embodiments, “chemical vapor deposition” refers to a process in which films of materials are deposited from the vapor phase by decomposition of chemicals on a substrate surface. In CVD, a substrate surface is exposed to precursors and/or co-reagents simultaneously or substantially simultaneously. A particular subset of CVD processes commonly used in LED manufacturing use metalorganic precursor chemical and are referred to as MOCVD or metalorganic vapor phase epitaxy (MOVPE). As used herein, “substantially simultaneously” refers to either co-flow or where there is overlap for a majority of exposures of the precursors.

As used herein according to some embodiments, “plasma enhanced atomic layer deposition (PEALD)” refers to a technique for depositing thin films on a substrate. In some examples of PEALD processes relative to thermal ALD processes, a material may be formed from the same chemical precursors, but at a higher deposition rate and a lower temperature. In a PEALD process, in general, a reactant gas and a reactant plasma are sequentially introduced into a process chamber having a substrate in the chamber. The first reactant gas is pulsed in the process chamber and is adsorbed onto the substrate surface. Thereafter, the reactant plasma is pulsed into the process chamber and reacts with the first reactant gas to form a deposition material, e.g., a thin film on a substrate. Similar to a thermal ALD process, a purge step may be conducted between the deliveries of each of the reactants.

As used herein according to one or more embodiments, “plasma enhanced chemical vapor deposition (PECVD)” refers to a technique for depositing thin films on a substrate. In a PECVD process, a source material, which is in gas or liquid phase, such as a gas-phase III-nitride material or a vapor of a liquid-phase III-nitride material that have been entrained in a carrier gas, is introduced into a PECVD chamber. A plasma-initiated gas is also introduced into the chamber. The creation of plasma in the chamber creates excited radicals. The excited radicals are chemically bound to the surface of a substrate positioned in the chamber, forming the desired film thereon.

In one or more embodiments, the epitaxial stack 300 is manufactured by placing the substrate 302 in a metalorganic vapor-phase epitaxy (MOVPE) reactor so that the layers of the VTF LED device with embedded contacts are grown epitaxially.

FIG. 4 is a cross-sectional view of an embedded contact vertical thin-film (VTF) LED device 400. The device 400 includes the epitaxial stack 330 of FIG. 3, including the multiple quantum well layer 312. The epitaxial stack 330 is deposited on the substrate 302 during a step in the manufacture of the VTF LED device 400 according to one or more embodiments. To form the VTF LED device 400 of FIG. 4, the AlInGaP layers 304, 306 are on the substrate and the p-type eighth layer 322 comprising gallium phosphide (GaP) is on the top of the epitaxial stack and exposed.

In one or more embodiments, the epitaxial stack 330 has a combined thickness in a range of from 1 μm to 10 μm, including a range of from 2 μm to 7 μm, and a range of from 3 μm to 6 μm. In one or more specific embodiments, the epitaxial stack 330 has a thickness of about 5 μm, including about 4.5 μm.

In one or more embodiments, the VTF LED device 400 is a red-emitting device. The device 400 includes a first dielectric layer 404 deposited on the epitaxial stack 330. The first dielectric layer 404 comprises any suitable dielectric material. In one or more embodiments, suitable dielectric materials include, but are not limited to, silicon oxide (SiOₓ), silicon nitride (SiN), silicon carbide (SiC), aluminum oxide (AlOₓ), aluminum nitride (AlN) and combinations thereof. The skilled artisan will recognize that the use of formulas like SiOₓ, to represent silicon oxide, does not imply any particular stoichiometric relationship between the elements. The formula merely identifies the primary elements of the film. In one or more embodiments, the first dielectric layer 404 comprises silicon oxide (SiOₓ).

In one or more embodiments, a portion of the first dielectric layer 404 is removed to form dielectric openings (not illustrated) on a top surface of the epitaxial stack 330. In one or more embodiments, the dielectric opening exposes the group III-V semiconductor material layers of the epitaxial stack 330.

In one or more embodiments, a first metal contact 414 and a second metal contact 416 are formed within the dielectric openings of the first dielectric layer 404 to contact the epitaxial stack 330.

In one or more embodiments, a first metal contact 414 contacts the aluminum indium gallium phosphide (AlInGaP) materials of the epitaxial stack. The first metal contact 414 may comprise any suitable metal known to the skilled artisan. In one or more embodiments, the first metal contact 414 comprises one or more of gold (Au), germanium (Ge), and nickel (Ni). In one or more specific embodiments, the first metal contact 414 comprises an alloy of one or more of gold (Au) and germanium (Ge). In one or more embodiments, the first metal contact 414 comprises gold germanium (AuGe) alloy.

In one or more embodiments, a second metal contact 416 is formed within the dielectric openings of the first dielectric layer 404. The second metal contact 416 contacts the p-type gallium phosphide (GaP) eighth layer 322 of the epitaxial stack 330. The second metal contact 416 is embedded within the first dielectric layer 404. The second metal contact 416 may comprise any suitable material known to the skilled artisan. In one or more embodiments, the second metal contact 416 comprises one or more of gold (Au), and zinc (Zn). In specific embodiments, the second metal contact 416 comprises an alloy of gold (Au) and zinc (Zn). In one or more embodiments, the second metal contact 416 comprises gold zinc (AuZn) alloy.

In one or more embodiments, a reflective metal layer 406 is formed on the first dielectric layer 404 at the interface. Without intending to be bound by theory, it is thought that the reflective metal layer 406 may promote current spreading through the p-type gallium phosphide (GaP) vias from bond pads 420, as illustrated in FIG. 5 and FIG. 6. The reflective metal layer 406 may comprise any suitable material known to the skilled artisan. In one or more embodiments, the reflective metal layer 406 comprises one or more of aluminum (Al), platinum (Pt), silver (Ag), gold (Au), and the like. In other embodiments, the reflective metal layer 406 may comprise a bilayer of a reflective material (i.e., one or more of aluminum (Al), platinum (Pt), silver (Ag), and the like) and indium tin oxide (ITO), with the ITO being the part of the bilayer in direct contact with the first dielectric layer 404. In one or more specific embodiments, the reflective metal layer 406 comprises silver (Ag). In other embodiments, possible structures include GaP plus a thin GaP:C (carbon doped layer) in contact with AuZn metal or ITO. In other embodiments, the metal contact may comprise silver (Ag).

In one or more embodiments, a second dielectric layer 408 is formed on the reflective metal layer 406, such that the reflective metal layer 406 is located between the first dielectric layer 404 and the second dielectric layer 408. In other embodiments, the first dielectric layer 404 comprises a distributed Bragg reflector (DBR) layer stack comprising one or more of silicon oxide (SiOₓ), titanium oxide (TiOₓ), and niobium oxide (Nb_{y}Oₓ). The second dielectric layer 408 comprises any suitable dielectric material. In one or more embodiments, suitable dielectric materials include, but are not limited to, silicon oxide (SiOₓ), silicon nitride (SiN), silicon carbide (SiC), aluminum oxide (AlOₓ), aluminum nitride (AlN) and combinations thereof. In one or more embodiments, the second dielectric layer 408 comprises silicon oxide (SiOₓ). In one or more embodiments, the second dielectric layer 408 is present to isolate or accommodate the bonding layer 412.

In one or more embodiments, a metal layer 410 is formed on the second dielectric layer 408. The metal layer 410 can comprise any suitable metal known to the skilled artisan. In one or more embodiments, the metal layer 410 comprises one or more of aluminum (Al), titanium (Ti), platinum (Pt), silver (Ag), gold (Au), and the like. In specific embodiments, the metal layer 410 comprises silver (Ag). In one or more embodiments, a bonding layer 412 is formed on the metal layer 410. In one or more embodiments, the bonding layer 412 is deposited and fabricated to provide bond pads 420 that contact exposed portions of the reflective metal layer 406.

FIG. 6A and FIG. 6B are cross-sectional views of a vertical thin-film (VTF) LED device 500 with embedded contacts, where the epitaxial configuration corresponds to FIG. 3. The dielectric layers and reflective metal layers correspond to those described with respect to FIG. 4. In one or more embodiments, the epitaxial stack 330 is etched away to form the bond pad metallization. In one or more embodiments, bond pad metallization extends to the reflective metal layer 406 for current spreading through the second metal contact 416 to the p-type gallium phosphide (GaP) regions of the epitaxial stack 330. In one or more embodiments, the second dielectric layer 410 covers the bonding layer 412 to isolate the bond pad 420, i.e., the anode, from the bonding layer 412, i.e., the cathode. Referring to FIG. 6B, the reflective metal layer 406, which comprises a p-metal, extends into the bondpad 420 area to form an electrical contact with bondwire.

### Embodiments

Various embodiments are listed below. It will be understood that the embodiments listed below may be combined with all aspects and other embodiments in accordance with the scope of the invention.

Embodiment (a). A vertical thin-film light emitting diode (LED) device comprising: an epitaxial stack comprising a plurality of group III-V semiconductor material layers, including binary, ternary, and quaternary alloys of gallium (Ga), aluminum (Al), indium (In), and phosphorus (P) and a multiple quantum well layer on a substrate, wherein at least one of the plurality of group III-V semiconductor material layers is a low confinement layer (LCL) comprising aluminum indium gallium phosphide (AlInGaP); a first dielectric layer on the epitaxial stack; an n-contact and a p-contact within the first dielectric layer; and a metal layer on the first dielectric layer in electrical contact with the plurality of group III-V semiconductor material layers.

Embodiment (b). The vertical thin-film (VTF) light emitting diode (LED) of embodiment (a), wherein at least one of the plurality of group III-V semiconductor material layers comprise an aluminum indium phosphide (AlInP) layer.

Embodiment (c). The vertical thin-film (VTF) light emitting diode (LED) of embodiment (a) to embodiment (b), wherein at least one of the plurality of group III-V semiconductor material layers comprise an aluminum indium gallium phosphide (AlInGaP) layer.

Embodiment (d). The vertical thin-film (VTF) light emitting diode (LED) of embodiment (a) to embodiment (c), wherein the low confinement layer (LCL) contains in a range of from about 30% to about 40% aluminum indium gallium phosphide (AlInGaP).

Embodiment (e). The vertical thin-film (VTF) light emitting diode (LED) of embodiment (a) to embodiment (d), wherein the low confinement layer (LCL) has a thickness in a range of from 2 μm to 5 μm.

Embodiment (f). The vertical thin-film (VTF) light emitting diode (LED) of embodiment (a) to embodiment (e), wherein one of the plurality of group III-V semiconductor material layers comprise an aluminum (Al) layer.

Embodiment (g). The vertical thin-film (VTF) light emitting diode (LED) of embodiment (a) to embodiment (e), wherein the metal layer comprises one or more of aluminum (Al), platinum (Pt), and silver (Ag).

Embodiment (h). The vertical thin-film (VTF) light emitting diode of embodiment (a) to embodiment (g), further comprising a second dielectric layer on the metal layer.

Embodiment (i). The vertical thin-film (VTF) light emitting diode (LED) of embodiment (a) to embodiment (h), further comprising a bonding layer.

Embodiment (j). The vertical thin-film (VTF) light emitting diode (LED) of embodiment (a) to embodiment (i), wherein the P-contact comprises an alloy of gold (Au) and zinc (Zn).

Embodiment (k). The vertical thin-film (VTF) light emitting diode (LED) of embodiment (a) to embodiment (j), wherein the N-contact comprises an alloy of gold (Au) and germanium (Ge).

Embodiment (l). The vertical thin-film (VTF) light emitting diode (LED) of embodiment (a) to embodiment (k), wherein the first dielectric layer comprises one or more of silicon oxide (SiOₓ), titanium oxide (TiOₓ), niobium oxide (Nb_{y}Oₓ), silicon nitride (SiN), silicon carbide (SiC), aluminum oxide (AlOₓ), and aluminum nitride (AlN).

Embodiment (m). A method of manufacturing a vertical thin-film (VTF) LED, the method comprising: sequentially forming a plurality of group III-V semiconductor material layers, including binary, ternary, and quaternary alloys of gallium (Ga), aluminum (Al), indium (In), and phosphorus (P) and a multiple quantum well layer to form an epitaxial stack on a substrate, wherein at least one of the plurality of group III-V semiconductor material layers is a low confinement layer (LCL) comprising aluminum indium gallium phosphide (AlInGaP); depositing a first dielectric layer on the epitaxial stack; removing a portion of the first dielectric layer to form openings in the dielectric layer, the openings exposing the plurality of group III-V semiconductor material layers; forming a P-contact in the openings in the dielectric layer; forming a metal layer on the first dielectric layer in electrical contact with the plurality of group III-V semiconductor material layers; forming a bond pad; depositing a second dielectric layer on the metal layer; and forming an N-contact on the epitaxial stack.

Embodiment (n). The method of embodiment (m), further comprising annealing the epitaxial stack prior to forming the N-contact and the P-contact in the dielectric openings.

Embodiment (o). The method of embodiment (m) to embodiment (n), wherein at least one of the plurality of group III-V semiconductor material layers comprise an aluminum indium phosphide (AlInP) layer.

Embodiment (p). The method of embodiment (m) to embodiment (o), wherein at least one of the plurality of group III-V semiconductor material layers comprise an aluminum (Al) layer.

Embodiment (q). The method of embodiment (m) to embodiment (p), wherein the metal layer comprises one or more of aluminum (Al), platinum (Pt), and silver (Ag).

Embodiment (r). The method of embodiment (m) to embodiment (q), wherein the P-contact comprises an alloy of gold (Au) and zinc (Zn).

Embodiment(s). The method of embodiment (m) to embodiment (r), wherein the N-contact comprises an alloy of one or more of gold (Au), germanium (Ge), and nickel (Ni).

Embodiment (t). The method of embodiment (m) to embodiment(s), wherein the first dielectric layer comprises one or more of silicon oxide (SiOₓ), titanium oxide (TiOₓ), niobium oxide (Nb_{y}Oₓ), silicon nitride (SiN), silicon carbide (SiC), aluminum oxide (AlOₓ), and aluminum nitride (AlN).

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to the terms first, second, third, etc. may be used herein to describe various elements, and these elements should not be limited by these terms. These terms may be used to distinguish one element from another.

Reference throughout this specification to a layer, region, or substrate as being “on” or extending “onto” another element, means that it may be directly on or extend directly onto the other element or intervening elements may also be present. When an element is referred to as being “directly on” or extending “directly onto” another element, there may be no intervening elements present. Furthermore, when an element is referred to as being “connected” or “coupled” to another element, it may be directly connected or coupled to the other element and/or connected or coupled to the other element via one or more intervening elements. When an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A vertical thin-film (VTF) light emitting diode (LED) comprising:
an epitaxial stack comprising a plurality of group III-V semiconductor material layers, including binary, ternary, and quaternary alloys of gallium (Ga), aluminum (Al), indium (In), and phosphorus (P) and a multiple quantum well layer on a substrate, wherein at least one of the plurality of group III-V semiconductor material layers is a low confinement layer (LCL) comprising aluminum indium gallium phosphide (AlInGaP);
a first dielectric layer on the epitaxial stack;
an n-contact and a p-contact within the first dielectric layer; and
a metal layer on the first dielectric layer in electrical contact with the plurality of group III-V semiconductor material layers.

2. The vertical thin-film (VTF) light emitting diode (LED) of claim 1, wherein at least one of the plurality of group III-V semiconductor material layers comprise an aluminum indium phosphide (AlInP) layer.

3. The vertical thin-film (VTF) light emitting diode (LED) of claim 1, wherein at least one of the plurality of group III-V semiconductor material layers comprise an aluminum indium gallium phosphide (AlInGaP) layer.

4. The vertical thin-film (VTF) light emitting diode (LED) of claim 1, wherein the low confinement layer (LCL) contains in a range of from about 30% to about 40% aluminum indium gallium phosphide (AlInGaP).

5. The vertical thin-film (VTF) light emitting diode (LED) of claim 1, wherein the low confinement layer (LCL) has a thickness in a range of from 2 μm to 5 μm.

6. The vertical thin-film (VTF) light emitting diode (LED) of claim 1, wherein one of the plurality of group III-V semiconductor material layers comprise an aluminum (Al) layer.

7. The vertical thin-film (VTF) light emitting diode (LED) of claim 1, wherein the metal layer comprises one or more of aluminum (Al), platinum (Pt), and silver (Ag).

8. The vertical thin-film (VTF) light emitting diode of claim 7, further comprising a second dielectric layer on the metal layer.

9. The vertical thin-film (VTF) light emitting diode (LED) of claim 1, further comprising a bonding layer.

10. The vertical thin-film (VTF) light emitting diode (LED) of claim 1, wherein the P-contact comprises an alloy of gold (Au) and zinc (Zn).

11. The vertical thin-film (VTF) light emitting diode (LED) of claim 1, wherein the N-contact comprises an alloy of gold (Au) and germanium (Ge).

12. The vertical thin-film (VTF) light emitting diode (LED) of claim 1, wherein the first dielectric layer comprises one or more of silicon oxide (SiOₓ), titanium oxide (TiOₓ), niobium oxide (Nb_{y}Oₓ), silicon nitride (SiN), silicon carbide (SiC), aluminum oxide (AlOₓ), and aluminum nitride (AlN).

13. A method of manufacturing a vertical thin-film (VTF) LED, the method comprising:
sequentially forming a plurality of group III-V semiconductor material layers, including binary, ternary, and quaternary alloys of gallium (Ga), aluminum (Al), indium (In), and phosphorus (P) and a multiple quantum well layer to form an epitaxial stack on a substrate, wherein at least one of the plurality of group III-V semiconductor material layers is a low confinement layer (LCL) comprising aluminum indium gallium phosphide (AlInGaP);
depositing a first dielectric layer on the epitaxial stack;
removing a portion of the first dielectric layer to form openings in the dielectric layer, the openings exposing the plurality of group III-V semiconductor material layers;
forming a P-contact in the openings in the dielectric layer;
forming a metal layer on the first dielectric layer in electrical contact with the plurality of group III-V semiconductor material layers;
forming a bond pad;
depositing a second dielectric layer on the metal layer; and
forming an N-contact on the epitaxial stack.

14. The method of claim 13, further comprising annealing the epitaxial stack prior to forming the N-contact and the P-contact in the dielectric openings.

15. The method of claim 13, wherein at least one of the plurality of group III-V semiconductor material layers comprise an aluminum indium phosphide (AlInP) layer.

16. The method of claim 13, wherein at least one of the plurality of group III-V semiconductor material layers comprise an aluminum (Al) layer.

17. The method of claim 13, wherein the metal layer comprises one or more of aluminum (Al), platinum (Pt), and silver (Ag).

18. The method of claim 13, wherein the P-contact comprises an alloy of gold (Au) and zinc (Zn).

19. The method of claim 13, wherein the N-contact comprises an alloy of one or more of gold (Au), germanium (Ge), and nickel (Ni).

20. The method of claim 13, wherein the first dielectric layer comprises one or more of silicon oxide (SiOₓ), titanium oxide (TiOₓ), niobium oxide (Nb_{y}Oₓ), silicon nitride (SiN), silicon carbide (SiC), aluminum oxide (AlOₓ), and aluminum nitride (AlN).
